(19) United States
(12) Patent Application Publication
(10) Pub. No.: US 2025/0379105 A1
(43) Pub. Date: Dec. 11, 2025

(54) METHOD OF EVALUATING SEMICONDUCTOR WAFER AND METHOD OF MANUFACTURING SEMICONDUCTOR WAFER

(71) Applicant: SUMCO CORPORATION, Tokyo (JP)

(72) Inventor: Ryosuke TAKAHASHI, Tokyo (JP)

(73) Assignee: SUMCO CORPORATION, Tokyo (JP)

(21) Appl. No.: 18/998,828

(22) PCT Filed: May 18, 2023
(86) PCT No.: PCT/JP2023/018508

§ 371 Date: Jan. 27, 2025

(30) Foreign Application Priority Data
Aug. 4, 2022 (JP) 2022-124985

(51) Int. Cl. H01L 21/66

(52) U.S. Cl. CPC H01L 22/12

(57) ABSTRACT

A method of evaluating a semiconductor wafer, including carrying out surface treatments multiple times in which hydrofluoric acid and ozone water are supplied on a wafer surface, and performing a surface inspection in which the surface of the wafer is inspected by an inspection device before the treatment, after each treatment, and after completion of the multiple surface treatments, in which an LPD initially detected in the surface inspection after n-th surface treatment at a coordinate point where no LPD has been detected in the surface inspection before the treatment was performed is classified as a defect, and an estimated size of the defect that existed on the surface of the semiconductor wafer before the treatment was performed, at the coordinate point where the defect was detected, is calculated by regression analysis.

### CROSS REFERENCE TO RELATED APPLICATIONS

This application claims the benefit of priority to Japanese Patent Application No. 2022-124985 filed on Aug. 4, 2022, which is expressly incorporated herein by reference in its entirety.

### TECHNICAL FIELD

The present invention relates to a method of evaluating a semiconductor wafer and a method of manufacturing a semiconductor wafer.

### BACKGROUND ART

A method based on light point defect (LPD) detected by a surface defect inspection device is widely used for evaluating defects in semiconductor wafers (see, for example, PTL 1 to PTL 3 (the entire disclosures of which are expressly incorporated herein by reference)). According to this method, the presence or absence and size of a defect on a semiconductor wafer surface can be evaluated by irradiating the semiconductor wafer surface to be evaluated with light and detecting the radiated light (scattered light or reflected light) from this surface.
PTL 1: Japanese Patent Application Publication No. 2016-212009
PTL 2: Japanese Patent Application Publication No. 2019-47108
PTL 3: Japanese Patent Application Publication No. 2020-106399

### SUMMARY OF INVENTION

The surface of a semiconductor wafer may have processing-induced defects caused by processing implemented in the manufacturing process. These processing-induced defects may include processing-induced microdefects of sizes that are smaller than the detection limit size of a surface defect inspection device. For example, such processing-induced microdefects are difficult to detect with the conventional evaluation methods such as those described in PTL 1 to PTL 3. However, if information about such processing-induced microdefects could be obtained, it would make it possible to manufacture high-quality semiconductor wafers having fewer processing-induced microdefects, for example, by modifying the manufacturing conditions of semiconductor wafers based on that information so as to suppress the occurrence of processing-induced microdefects.

One aspect of the present invention aims to provide a new evaluation method capable of evaluating processing-induced microdefects that occur on the surface of a semiconductor wafer due to processing implemented in the manufacturing process.

One aspect of the present invention is as follows.

[1] A method of evaluating a semiconductor wafer (hereinafter also referred to as “wafer”), the method including:
carrying out a surface treatment on a surface of the semiconductor wafer multiple times, wherein
the surface treatment includes:
supplying hydrofluoric acid to the surface of the semiconductor wafer and supplying ozone water to the surface of the semiconductor wafer after the supply of the hydrofluoric acid, or
supplying ozone water to the surface of the semiconductor wafer and supplying hydrofluoric acid to the surface of the semiconductor wafer after the supply of the ozone water, and
the method further includes:
performing a surface inspection in which the surface of the semiconductor wafer is inspected by a surface defect inspection device before the surface treatment, after each surface treatment, and after completion of the multiple surface treatments, and
an LPD initially detected in the surface inspection after n-th surface treatment at a coordinate point where no LPD has been detected in the surface inspection before the surface treatment was performed is classified as a processing-induced defect, wherein
the n is an integer of 1 or more and (N−1) or less, with N being a total number of the surface treatments, and
an estimated size of the processing-induced defect that existed on the surface of the semiconductor wafer before the surface treatment was performed, at the coordinate point where the processing-induced defect was detected, is calculated by regression analysis in which a detected size of an LPD detected in the surface inspection after completion of the multiple surface treatments is taken as an objective variable, and a total number (N−n) of surface treatments carried out after the initial detection is taken as an explanatory variable.
   [2] The method of evaluating a semiconductor wafer according to [1], wherein the surface treatment includes supplying ozone water to the surface of the semiconductor wafer, supplying hydrofluoric acid to the surface of the semiconductor wafer after the supply of the ozone water, and supplying ozone water to the surface of the semiconductor wafer after the supply of the hydrofluoric acid.
   [3] The method of evaluating a semiconductor wafer according to [1] or [2], wherein the regression analysis is performed by regression equation below:

$$y = ax + b ,$$

with the objective variable being y and the explanatory variable being x, and
in the regression equation, a is a slope determined by the regression analysis, and b is an intercept determined by the regression analysis, and
the estimated size of the processing-induced defect that existed on the surface of the semiconductor wafer before the surface treatment was carried out, at the coordinate point where the processing-induced defect was detected, is determined as the b.
   [4] The method of evaluating a semiconductor wafer according to any of [1] to [3], wherein the ozone water has an ozone concentration of 20 ppm or more and 30 ppm or less, based on mass.
   [5] The method of evaluating a semiconductor wafer according to any of [1] to [4], wherein the hydrofluoric acid has a hydrogen fluoride concentration of 0.1% by mass or more and 1.0% by mass or less.
   [6] The method of evaluating a semiconductor wafer according to any of [1] to [5], wherein time of the supply of the hydrofluoric acid is 20 sec or less.
   [7] A method of manufacturing a semiconductor wafer, the method including:
manufacturing a semiconductor wafer under a manufacturing condition to be evaluated;
evaluating the manufactured semiconductor wafer by the semiconductor wafer evaluation method according to any of [1] to [6];
based on results of the evaluation, determining a manufacturing condition obtained by modifying the manufacturing condition to be evaluated as a subsequent manufacturing condition, or determining the manufacturing condition to be evaluated as a manufacturing condition to be used continuously; and
manufacturing the semiconductor wafer under the determined manufacturing conditions.
   [8] The method of manufacturing a semiconductor wafer according to [7], wherein the manufacturing condition to be modified is a polishing condition of a surface of the semiconductor wafer.

According to one aspect of the present invention, it is possible to evaluate processing-induced microdefects that occur on the semiconductor wafer surface due to processing implemented in the manufacturing process.

### BRIEF DESCRIPTION OF THE DRAWINGS

FIG. 1 is a process flow in the evaluation method.

FIG. 2 is a schematic diagram of a specific example of the in-plane distribution of LPDs on the wafer surface before and after repeated surface treatment.

FIG. 3 is an explanatory drawing illustrating how processing-induced microdefects are made more apparent by surface treatment.

FIG. 4 is a graph showing the relationship between the detected size of LPD for each defect and the number of surface treatments in an example in which surface inspection before surface treatment was performed on the surface of a silicon wafer (polished wafer) and then surface treatment and surface inspection were repeated a total of six times, and five defects (defect 1 to defect 5) that were detected as LPDs in the surface inspection before surface treatment were randomly selected.

FIG. 5 is a graph showing the relationship between the total number of surface treatments carried out after the initial detection and the detected size of LPDs in the surface inspection after the final surface treatment for LPDs that were initially detected in the surface inspection after the n-th surface treatment, in the case where surface inspection preceding surface treatment was performed on the surface of a silicon wafer (polished wafer) and then surface treatment and surface inspection were repeatedly performed.

FIG. 6 shows the detected size of LPD before surface treatment of LPDs detected as immovable defects in the example shown in FIG. 5 (right figure), and the estimated size calculated at the coordinate point where an increased defect was detected (left figure).

### DESCRIPTION OF EMBODIMENTS

### Method of Evaluating Semiconductor Wafer

One aspect of the present invention relates to a method of evaluating a semiconductor wafer, including: carrying out a surface treatment on a surface of the semiconductor wafer multiple times, wherein the surface treatment includes supplying hydrofluoric acid to the surface of the semiconductor wafer and supplying ozone water to the surface of the semiconductor wafer after the supply of hydrofluoric acid, or supplying ozone water to the surface of the semiconductor wafer and supplying hydrofluoric acid to the surface of the semiconductor wafer after the supply of ozone water, and the method further includes performing a surface inspection in which the surface of the semiconductor wafer is inspected by a surface defect inspection device before the surface treatment, after each surface treatment, and after the multiple surface treatments are completed, and an LPD initially detected in the surface inspection after the n-th surface treatment at a coordinate point where no LPD was detected in the surface inspection before the surface treatment was performed is classified as a processing-induced defect, wherein the n is an integer of 1 or more and (N−1) or less, N being the total number of the surface treatments, and an estimated size of the processing-induced defect that existed on the surface of the semiconductor wafer before the surface treatment was carried out, at the coordinate point where the processing-induced defect was detected, is calculated by regression analysis in which a detected size of an LPD detected in the surface inspection after the multiple surface treatments are completed is taken as an objective variable, and the total number (N−n) of surface treatments carried out after the initial detection is taken as an explanatory variable.

The above evaluation method will be described in further detail below.

### <Semiconductor Wafer to Be Evaluated>

The semiconductor wafer to be evaluated by the above evaluation method can be any of various semiconductor wafers that are generally used as semiconductor substrates. For example, specific examples of semiconductor wafers include various silicon wafers. Silicon wafers can be, for example, single crystal silicon wafers that have been cut out from a silicon single crystal ingot and then processed in various ways, such as polished wafers that have been polished to have a polished surface. The diameter of the semiconductor wafer to be evaluated is, for example, 200 mm or less and 200 mm or more (for example, 200 mm, 300 mm, or 450 mm), but is not particularly limited.

### <Surface Inspection by Surface Defect Inspection Device>

As a surface defect inspection device, a known surface defect inspection device that can radiate light onto the surface of a semiconductor wafer and detect the light radiated from this surface (scattered light or reflected light) can be used. Such a surface defect inspection device is generally called a light scattering surface defect inspection device, surface inspection apparatus, and the like. A specific example of the surface defect inspection device is a laser surface defect inspection device. The laser surface defect inspection device usually scans the surface of the semiconductor wafer to be evaluated with a laser light and detects the processing-induced defects and adherent particles on the surface of the wafer to be evaluated as bright spots (LPDs) by the radiated light (scattered light or reflected light). In addition, by measuring the radiated light from the LPDs, the positions (specifically, coordinate points) of the processing-induced defects and adherent particles on the surface of the semiconductor wafer to be evaluated and the size detected as LPDs can be obtained. Such detected size of LPD is usually output by the analysis unit of the surface defect inspection device by comparing the intensity of the radiated light from the LPD with the intensity of the radiated light from standard particles such as silica particles. As the laser light, ultraviolet light, visible light, and the like can be used, and the wavelength thereof is not particularly limited. Ultraviolet light refers to light in a wavelength range of less than 400 nm, and visible light refers to light in a wavelength range of 400 nm to 600 nm. The analysis unit of the laser surface defect inspection device usually acquires information on the two-dimensional position coordinates (X coordinates and Y coordinates) on the surface of the object under evaluation for each of the plurality of detected LPDs and can create an LPD map showing the in-plane distribution state of the LPDs on the surface of the object under evaluation from the obtained two-dimensional position coordinate information. Specific examples of commercially available laser surface defect inspection devices include Surfscan series SP1, SP2, SP3, SP5, and SP7 manufactured by KLA-Tencor Corporation. However, these devices are merely examples, and other types of surface defect inspection devices can also be used.

As described above, it is difficult to evaluate processing-induced microdefects that are smaller than the detection limit size of a surface defect inspection device by the usual surface inspection performed by the surface defect inspection device. In contrast, according to the above evaluation method, it is possible to evaluate such processing-induced microdefects by going through the following steps.

### <Process Flow>

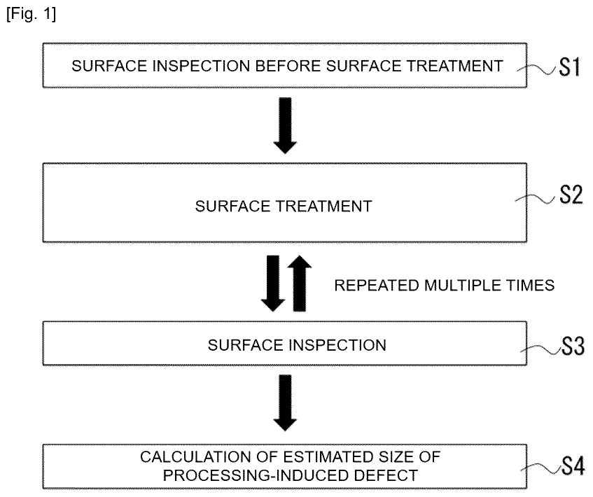

FIG. 1 shows the process flow of the above evaluation method. Below, various steps in the above evaluation method will be described following the process flow shown in FIG. 1.

### (Surface Inspection Before Surface Treatment, Repetition of Surface Treatment and Surface Inspection)

In the above evaluation method, surface treatment is carried out multiple times on the semiconductor wafer to be evaluated (repetition of S2 in FIG. 1). Before the multiple surface treatments are carried out, a surface inspection of the surface of the semiconductor wafer to be evaluated (surface to be evaluated) is performed (S1 in FIG. 1).

Then, the first surface treatment is carried out on the surface to be evaluated (S2 in FIG. 1), and after this surface treatment, a surface inspection of the surface to be evaluated is performed (S3 in FIG. 1). Then, the surface treatment and the surface inspection after the surface treatment are performed multiple times.

In one embodiment, in the first surface treatment and each subsequent surface treatment, hydrofluoric acid is supplied to the surface to be evaluated (hereinafter also referred to as the “hydrofluoric acid supply step”), and ozone water is supplied to the surface to be evaluated after the supply of hydrofluoric acid (hereinafter also referred to as the “ozone water supply step for passivation”). This embodiment is referred to as “Method 1”. In Method 1, ozone water can be further supplied to the surface to be evaluated before the hydrofluoric acid supply step (hereinafter also referred to as “ozone water supply step for oxide film formation”). The implementation of the ozone water supply step for oxide film formation is optional, and is preferable. The reason why it is preferable will be described below.

Further, in another embodiment, ozone water is supplied to the surface to be evaluated in the first surface treatment and each subsequent surface treatment (hereinafter also referred to as “ozone water supply step for oxide film formation”), and hydrofluoric acid is supplied to the surface to be evaluated after the supply of ozone water (hereinafter also referred to as “hydrofluoric acid supply step”). This embodiment is referred to as “Method 2”.

Details of the surface treatments in Methods 1 and 2 will be described below. In addition, usually, after each surface treatment, the surface to be evaluated can be subjected to surface inspection after carrying out a drying treatment by a known method.

On the surface of a semiconductor wafer, there may be two types of defects: particles that are simply adherent to the surface, and defects that occurred due to the processing implemented in the manufacturing process as described above. The first surface treatment usually removes the particles that are adherent to the surface to be evaluated. Therefore, if an LPD detected in a surface inspection before surface treatment is not detected in the surface inspection after the first surface treatment at the coordinate point where the LPD was detected, the LPD can be assumed to be an LPD caused by the adherent particle. Such defects that are not detected as LPDs after the first surface treatment are referred to below as “disappearing defects.”

By contrast, an LPD detected in the surface inspection before surface treatment may be detected in the surface inspection after the first surface treatment, and even in the surface inspection after the surface treatment that is repeated thereafter, at the coordinate point where the LPD was detected. Such LPDs can be assumed to be LPDs caused by processing defects that are equal to or larger than the detection limit size of the surface defect inspection device. Such processing defects are referred to below as “immovable defects.”

Meanwhile, the surface treatment can make processing defects more apparent. Therefore, processing-induced microdefects that were not detected as LPDs in the surface inspection before surface treatment because these defects were smaller than the detection limit size of the surface defect inspection device can be detected as LPDs in the surface inspection after the first or second or subsequent surface treatments. Such processing-induced microdefects will be hereinafter referred to as “increased defects.” How the processing defects are made more apparent by the surface treatment will be described in detail below.

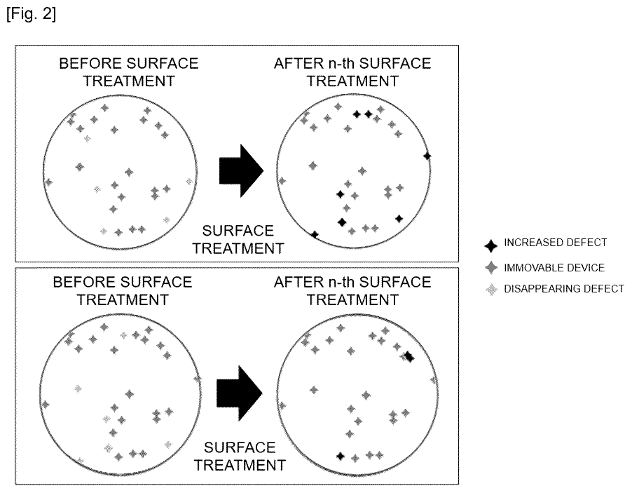

FIG. 2 shows a schematic diagram of a specific example of the in-plane distribution of LPDs on the wafer surface before and after repeated surface treatments. Both the upper and lower figures in FIG. 2 include disappearing defects, immovable defects, and increased defects. From the position information (coordinate information) of LPDs before and after surface treatment as shown in FIG. 2, it can be estimated that:
the disappearing defects that exist only before surface treatment are adherent particles,
the immovable defects that exist in the same position before and after surface treatment are large-size processing-induced defects that are equal to or larger than the detection limit size of the surface defect inspection device, and
the increased defects that did not exist before surface treatment but exist only after the n-th surface treatment are processing-induced microdefects that have been made more apparent by the surface treatments of n-times.

Where the increased defect becomes a disappearing defect as a result of the next surface treatment, it is preferable to exclude it as an adherent particle. Here, “n” is an integer of 1 or more and (N−1) or less, where N is the total number of multiple surface treatments.

Next, how the processing defects are made more apparent by the surface treatment will be described in greater detail.

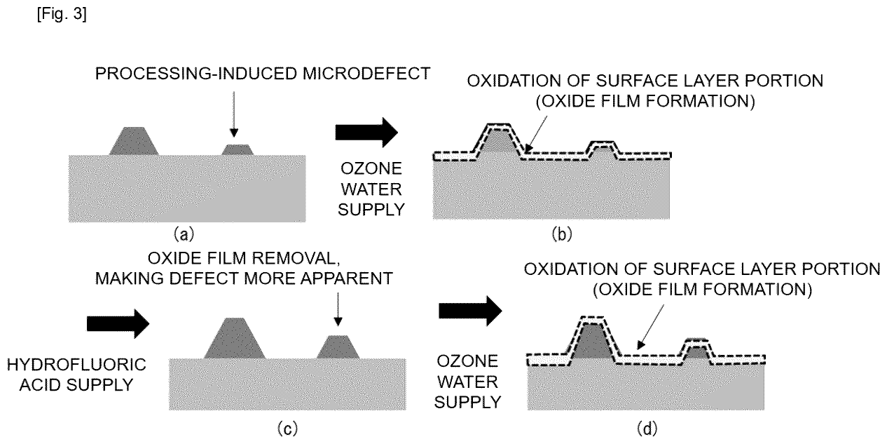

FIG. 3 is an explanatory drawing illustrating how processing-induced microdefects are made more apparent by surface treatment of Method 1 described above.

The processing-induced microdefect can be a protrusion-shaped defect, as shown in, for example, FIG. 3(a). A specific example of such a protrusion-shaped defect is a PID (Polished Induced Defect). A PID is a protrusion-shaped defect introduced into the semiconductor wafer surface in the polishing process.

Where ozone water is supplied to the wafer surface having a processing-induced microdefect (ozone water supply step for oxide film formation), the wafer surface is oxidized by the ozone water, and an oxide film is formed (FIG. 3(b)). A natural oxide film is usually formed on the surface to be evaluated before the hydrofluoric acid supply step in the first surface treatment and the second and subsequent surface treatments is implemented. Therefore, the implementation of the ozone water supply step for oxide film formation is optional, and preferable. The reason why it is preferable to perform the ozone water supply step for oxide film formation will be described below.

Preferably, where the ozone water supply step for oxide film formation is performed and then hydrofluoric acid is supplied to the wafer surface (hydrofluoric acid supply step), at least a part of the oxide film on the wafer surface is removed (so-called etching) (FIG. 3(c)). This makes it possible to increase the size of the processing-induced microdefects (i.e., make them more apparent). In order to make the processing-induced microdefects more apparent, it is preferable to perform the hydrofluoric acid supply step so that the oxide film on the wafer surface is not completely peeled off and a part thereof remains. Such a hydrofluoric acid supply step will be described below.

The subsequent supply of ozone water (ozone water supply step for passivation) is a process in which contamination of the wafer surface by organic matter and the like is suppressed by inactivating the wafer surface after the hydrofluoric acid supply step (so-called passivation process). The ozone water supply step for passivation can oxidize the wafer surface after the hydrofluoric acid supply step and form an oxide film (FIG. 3(d)), thereby inactivating the wafer surface.

However, it is not essential to inactivate the wafer surface after the hydrofluoric acid supply step. Therefore, when performing the surface treatment of Method 2 described above, it is possible to perform the ozone water supply step for oxide film formation, thereafter perform the hydrofluoric acid supply step, and then perform the surface inspection without implementing the ozone water supply step for passivation.

### (Calculation of Estimated Size of Processing-Induced Microdefect by Regression Analysis)

Since the size of the above-mentioned processing-induced microdefect is smaller than the detection limit size of the surface defect inspection device used for the surface inspection, the detected size of LPD of the processing-induced microdefect cannot be obtained as a result of the surface inspection before the surface treatment.

Meanwhile, in the course of comprehensive research, the present inventor has found that the amount of change in size of processing-induced defects due to each of the surface treatments performed multiple times can be considered to be constant.

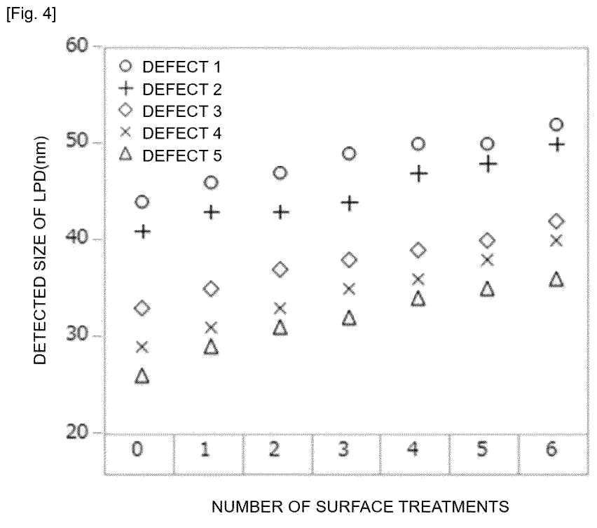

FIG. 4 is a graph showing the relationship between the detected size of LPD for each defect and the number of surface treatments in an example in which surface inspection before surface treatment was performed on the surface of a silicon wafer (polished wafer) and then surface treatment and surface inspection were repeated a total of six times, and five defects (defect 1 to defect 5) that were detected as LPDs in the surface inspection before surface treatment were randomly selected. Each of the six surface treatments was performed under the same surface treatment conditions. It can be confirmed from FIG. 4 that the amount of change in size of processing-induced defects due to each surface treatment performed multiple times can be considered to be constant.

As a result of additional diligent research, the present inventor has newly found that, under the assumption that the amount of change in size of processing-induced microdefects due to each of the surface treatments performed multiple times is constant, the size of the processing-induced microdefect that is estimated to be detectable by a surface defect inspection device with a smaller detection limit size can be calculated by regression analysis as follows.

First, an LPD initially detected in the surface inspection after the n-th surface treatment (as described above, n is an integer of 1 or more and (N−1) or less) at a coordinate point where no LPD was detected in the surface inspection before the surface treatment was performed is classified as a processing-induced defect (more specifically, the above-mentioned processing-induced microdefect). An estimated size of the processing-induced microdefect that existed on the surface of the semiconductor wafer before the surface treatment was carried out, at the coordinate point where the processing-induced microdefect was detected, is calculated by regression analysis in which the detected size of the LPD in the surface inspection after the multiple surface treatments are completed is taken as an objective variable, and the total number (N−n) of surface treatments carried out after the initial detection is taken as an explanatory variable.

The steps preceding the above calculation will be explained below in more detail with the following specific examples.

A polished wafer (single crystal silicon wafer) with a diameter of 300 mm was used as the sample semiconductor wafer for evaluation.

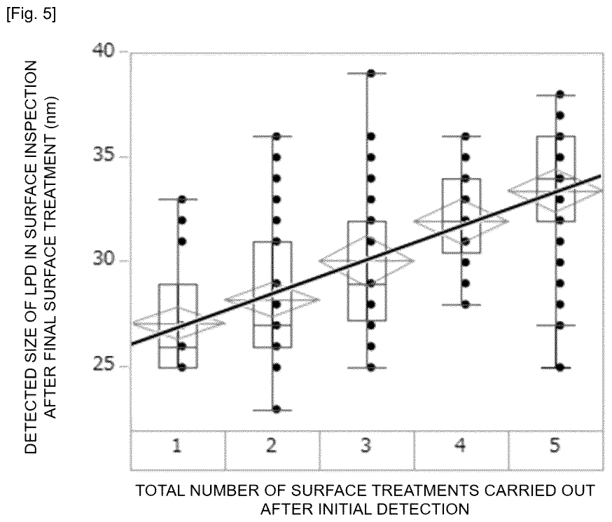

FIG. 5 is a graph showing the relationship between the total number of surface treatments carried out after the initial detection and the detected size of LPDs in the surface inspection after the final surface treatment for LPDs that were initially detected in the surface inspection after the n-th surface treatment, in the case where surface inspection preceding surface treatment was performed on the surface of a sample wafer and then surface treatment and surface inspection were repeatedly performed. The surface defect inspection device used was the SP7 of the Surfscan series (laser surface defect inspection devices) manufactured by KLA-Tencor Corporation, and the measurement mode used was High Sensitivity Oblique Mode (HSO Mode). Each channel of the HSO Mode has the following sensitivity.
DW10 (Dark-Field Wide 1 Oblique) channel: 15 nm
DW20 (Dark-Field Wide 2 Oblique) channel: 25 nm
DNO (Dark-Field Narrow Oblique) channel: 31 nm

Of the above channels, DW10 is the most sensitive. DW10 is highly sensitive to particles. Meanwhile, DW20 and DNO are highly sensitive to processing-induced defects.

In the example shown in FIG. 5, the total number of surface treatments is 6 (N=6). Therefore, for example, the plot with the horizontal axis of “1 time” in FIG. 5 relates to LPDs that were initially detected in the surface inspection after the fifth surface treatment and on which one more surface treatment (6 times-5 times) was subsequently carried out, and the plot with the horizontal axis of “2 times” relates to LPDs that were initially detected in the surface inspection after the fourth surface treatment and on which two more surface treatments (6 times-4 times) were subsequently carried out. The same is true for the plots with the horizontal axis of “3 times”, “4 times”, and “5 times”. In FIG. 5, a straight line is shown that is a linear approximation of the average values of the horizontal axis of 1 time to 5 times. From the results shown in FIG. 5, it can be confirmed that the LPDs that were initially detected with fewer surface treatments tend to have larger detected size of LPDs in the surface inspection after the final surface treatment. From these results, it can be said that the larger the size of the processing-induced microdefects on the wafer surface before surface treatment, the earlier they become apparent with fewer surface treatments, and the final detected size of LPDs tends to be larger. Furthermore, by statistically calculating the amount of change, it is possible to estimate the amount of size change due to one surface treatment. For example, where the detected size of LPD in the surface inspection after the final surface treatment (the sixth in the example shown in FIG. 5), i.e., after completion of the multiple surface treatments, is used as an objective variable, the total number of surface treatments (N−n) carried out after the initial detection is used as an explanatory variable, and the linear equation of the approximation line shown in FIG. 5 is used as the regression equation “y=ax+b”, the slope a and intercept b can be obtained by simple regression analysis. The estimated size of the processing-induced microdefect that existed on the surface of the semiconductor wafer before the surface treatment was carried out, at the coordinate point where the processing-induced microdefect was detected, can be thus calculated, for example, as the b. For example, by creating a regression equation in advance for each surface treatment condition, when performing surface treatment under that surface treatment condition thereafter, the estimated size of the processing-induced microdefect that existed on the surface of the semiconductor wafer before the surface treatment was carried out under that surface treatment condition can be calculated by regression analysis using the regression equation created in advance with the detected size of LPD in the surface inspection after completion of the multiple surface treatments as the objective variable and the total number of surface treatments (N−n) carried out after the initial detection as the explanatory variable.

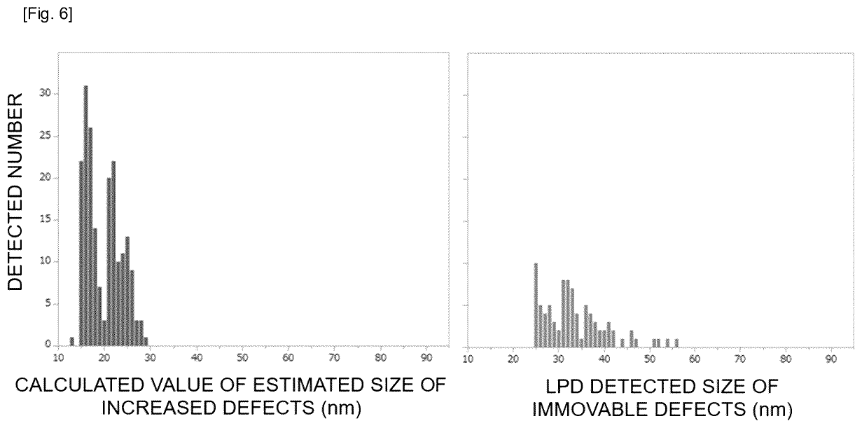

FIG. 6 shows the detected size of LPDs (right figure) before surface treatment for LPDs detected as immovable defects in the example shown in FIG. 5, and the estimated size (left figure) calculated at the coordinate points where the increased defects were detected. From FIG. 6, it can be confirmed that the above evaluation method makes it possible to detect processing-induced microdefects with a detected size of LPD of 25 nm or less, which cannot normally be detected by the surface defect inspection device used in the example shown in FIG. 5, by making the defects more apparent and detecting them with the surface defect inspection device, and that the estimated size can be calculated by the method described above.

### <Surface Treatment>

As described above, in the surface treatment performed multiple times in the above evaluation method, the surface treatment of Method 1 or Method 2 is performed. It is preferable to perform the multiple surface treatments under the same surface treatment conditions. Here, with regard to the “same surface treatment conditions”, it is assumed that fluctuations in conditions that may inevitably occur during preparation of the chemical solution for surface treatment, during surface treatment, and the like are allowed.

The total number N of surface treatments performed multiple times is 2 or more, and can be 3 or more, 4 or more, or 5 or more. Further, N can be, for example, 10 or less, 9 or less, 8 or less, 7 or less, or 6 or less. However, the higher the number of surface treatments, the finer defects induced by processing can be made apparent, so the number of surface treatments is not limited to the number exemplified here, and a larger number of surface treatments can be performed.

As the ozone water, for example, ozone water with an ozone concentration of 20 ppm or more and 30 ppm or less, based on mass, can be used. As the hydrofluoric acid, for example, hydrofluoric acid with a hydrogen fluoride concentration of 0.1% by mass or more and 1.0% by mass or less can be used. The supply of ozone water and hydrofluoric acid to the surface to be evaluated can be performed in the same manner as in the cleaning process usually carried out on semiconductor wafers. In the example shown in FIG. 4 and FIG. 5, ozone water having an ozone concentration of 25 ppm by mass and hydrofluoric acid having a hydrogen fluoride concentration of 1.0% by mass were used, and an ozone water supply step for oxide film formation, a hydrofluoric acid supply step, and an ozone water supply step for passivation were implemented in the same manner as in a cleaning process normally caried out on semiconductor wafers.

As regards the supply of ozone water, from the viewpoint of passivation treatment after the hydrofluoric acid supply step, it is preferable that the ozone water supply step for passivation be performed for a longer time than the ozone water supply step for oxide film formation. The supply time of ozone water can be, for example, about 10 sec to 60 sec in the ozone water supply step for oxide film formation, and about 20 sec to 60 sec in the ozone water supply step for passivation. In the example shown in FIG. 4 and FIG. 5, the supply time of ozone water is 15 sec in the ozone water supply step for oxide film formation, and 30 sec in the ozone water supply step for passivation.

In the hydrofluoric acid supply step, the supply time of hydrofluoric acid can be, for example, 1 sec or more, 2 sec or more, or 3 sec or more. As described above, in order to make processing-induced microdefects more apparent, it is preferable to perform the hydrofluoric acid supply step so that the oxide film formed before the hydrofluoric acid supply step is not completely peeled off and a part thereof remains. From this point of view, it is preferable that the hydrofluoric acid supply time be 20 sec or less. In the example shown in FIG. 4 and FIG. 5, the hydrofluoric acid supply time in the hydrofluoric acid supply step was 4 sec. As described above, it is preferable that the oxide film formed before the hydrofluoric acid supply step is not completely peeled off and a part thereof remains after the hydrofluoric acid supply step. Therefore, in the surface treatment of the above-mentioned Method 1, it is preferable to implement the ozone water supply step for oxide film formation before the hydrofluoric acid supply step.

### [Method of Manufacturing Semiconductor Wafer]

One aspect of the present invention relates to a method of manufacturing a semiconductor wafer, including: manufacturing a semiconductor wafer under a manufacturing condition to be evaluated; evaluating the manufactured semiconductor wafer by the above-described semiconductor wafer evaluation method; based on the results of the evaluation, determining a manufacturing condition obtained by modifying the manufacturing condition to be evaluated as the subsequent manufacturing condition, or determining the manufacturing condition to be evaluated as the manufacturing condition to be used continuously; and manufacturing the semiconductor wafer under the determined manufacturing condition.

The following can be exemplified as a specific embodiment of the above manufacturing method.

Semiconductor wafers are manufactured under the manufacturing condition A.

Separately, semiconductor wafers are manufactured under the manufacturing condition B that is different from the manufacturing condition A.

The manufacturing condition to be evaluated is the “manufacturing condition B.”

Evaluation wafers are sampled from the wafer group manufactured under the manufacturing conditions A and the wafer group manufactured under the manufacturing condition B, and the sampled wafers are evaluated using the evaluation method described above.

For example, where the evaluation results show that the total number of processing-induced microdefects classified as processing-induced defects in the above-described evaluation method in the evaluation wafers sampled from the wafer group manufactured under the manufacturing condition A is less than that of the evaluation wafers sampled from the wafer group manufactured under the manufacturing condition B, the manufacturing condition A can be determined to be the manufacturing condition that is less likely to cause processing-induced microdefects than the manufacturing condition B. In this case, the manufacturing condition B can be modified to be closer to the manufacturing condition A, and the manufacturing condition modified in this way can be taken as the improved manufacturing condition B, under which semiconductor wafers can be subsequently manufactured.

Furthermore, for example, where the representative value (average value, maximum value, and the like) of the estimated size of processing-induced microdefects classified as processing-induced defects that is calculated by the above-described evaluation method is larger in the evaluation wafers sampled from the group of wafers manufactured under the manufacturing condition B than in the evaluation wafers sampled from the group of wafers manufactured under the manufacturing condition A, the manufacturing condition B can be determined to be the manufacturing condition that is more likely to cause larger processing-induced microdefects than the manufacturing condition A. In this case, the manufacturing condition B can be modified to be closer to the manufacturing condition A, and the manufacturing condition modified in this way can be taken as the improved manufacturing condition B, under which semiconductor wafers can be subsequently manufactured.

The following can also be exemplified as a specific embodiment of the above manufacturing method.

First, the test manufacturing condition is determined in order to determine the manufacturing condition for manufacturing semiconductor wafers to be actually shipped as products (hereinafter referred to as “actual manufacturing condition”).

Semiconductor wafers are manufactured under the test manufacturing condition.

The semiconductor wafer manufactured under the test manufacturing condition is evaluated by the above-described evaluation method.

Based on the evaluation results, the manufacturing condition obtained by modifying the test manufacturing condition can be determined as the actual manufacturing condition, or the test manufacturing condition itself can be determined as the actual manufacturing condition. Then, semiconductor wafers can be manufactured under the determined actual manufacturing condition.

For example, where the evaluation results show that the total number of processing-induced microdefects classified as processing-induced defects in the above-described evaluation method in the semiconductor wafers manufactured under the test manufacturing condition exceeds a preset target value, the manufacturing condition obtained by modifying the test manufacturing condition so as to suppress the occurrence of processing-induced microdefects can be determined as the actual manufacturing condition.

Also, where the evaluation results show that the representative value (average value, maximum value, and the like) of the estimated size of the processing-induced microdefects classified as processing-induced defects that has been calculated in the above-described evaluation method in the semiconductor wafers manufactured under the test manufacturing condition exceeds a preset target value, the manufacturing condition obtained by modifying the test manufacturing condition so as to suppress the occurrence of processing-induced microdefects can be determined as the actual manufacturing condition.

As regards the manufacturing process of semiconductor wafers, for example, polished wafers can be manufactured by a manufacturing process including processing steps of cutting (slicing) wafers from semiconductor ingots such as silicon single crystal ingots, chamfering, rough polishing (for example, lapping), etching, mirror polishing (finish polishing), and a cleaning step performed between or after the above processing steps. Since PID, which is one type of processing-induced microdefects, is a defect that occurs in the polishing process, the manufacturing condition to be modified can be the condition for polishing the semiconductor wafer surface. Specifically, various changes in polishing conditions can be mentioned, such as replacement of polishing slurry, change in the composition of polishing slurry, replacement of polishing pad, change in the type of polishing pad, and change in the operating conditions of the polishing device.

One aspect of the present invention is useful in the field of manufacturing various semiconductor wafers such as polished wafers.

1. A method of evaluating a semiconductor wafer, the method comprising:
carrying out a surface treatment on a surface of the semiconductor wafer multiple times, wherein
the surface treatment comprises:
supplying hydrofluoric acid to the surface of the semiconductor wafer and supplying ozone water to the surface of the semiconductor wafer after the supply of the hydrofluoric acid, or
supplying ozone water to the surface of the semiconductor wafer and supplying hydrofluoric acid to the surface of the semiconductor wafer after the supply of the ozone water, and
the method further comprises:
performing a surface inspection in which the surface of the semiconductor wafer is inspected by a surface defect inspection device before the surface treatment, after each surface treatment, and after completion of the multiple surface treatments, and
an LPD initially detected in the surface inspection after n-th surface treatment at a coordinate point where no LPD has been detected in the surface inspection before the surface treatment was performed is classified as a processing-induced defect, wherein
the n is an integer of 1 or more and (N−1) or less, with N being a total number of the surface treatments, and
an estimated size of the processing-induced defect that existed on the surface of the semiconductor wafer before the surface treatment was performed, at the coordinate point where the processing-induced defect was detected, is calculated by regression analysis in which a detected size of an LPD detected in the surface inspection after completion of the multiple surface treatments is taken as an objective variable, and a total number (N−n) of the surface treatments carried out after the initial detection is taken as an explanatory variable.

2. The method of evaluating a semiconductor wafer according to according to claim 1,
wherein the surface treatment comprises supplying ozone water to the surface of the semiconductor wafer, supplying hydrofluoric acid to the surface of the semiconductor wafer after the supply of the ozone water, and supplying ozone water to the surface of the semiconductor wafer after the supply of the hydrofluoric acid.

3. The method of evaluating a semiconductor wafer according to claim 1,
wherein the regression analysis is performed by regression equation below:
$$y = ax + b ,$$
with the objective variable being y and the explanatory variable being x, and
in the regression equation, a is a slope determined by the regression analysis, and b is an intercept determined by the regression analysis, and
the estimated size of the processing-induced defect that existed on the surface of the semiconductor wafer before the surface treatment was carried out, at the coordinate point where the processing-induced defect was detected, is determined as the b.

4. The method of evaluating a semiconductor wafer according to claim 1,
wherein the ozone water has an ozone concentration of 20 ppm or more and 30 ppm or less, based on mass.

5. The method of evaluating a semiconductor wafer according to claim 1,
wherein the hydrofluoric acid has a hydrogen fluoride concentration of 0.1% by mass or more and 1.0% by mass or less.

6. The method of evaluating a semiconductor wafer according to claim 1,
wherein time of the supply of the hydrofluoric acid is 20 sec or less.

7. The method of evaluating a semiconductor wafer according to according to claim 1,
wherein the surface treatment comprises supplying ozone water to the surface of the semiconductor wafer, supplying hydrofluoric acid to the surface of the semiconductor wafer after the supply of the ozone water, and supplying ozone water to the surface of the semiconductor wafer after the supply of the hydrofluoric acid,
the regression analysis is performed by regression equation below:
$$y = ax + b ,$$
with the objective variable being y and the explanatory variable being x, and
in the regression equation, a is a slope determined by the regression analysis, and b is an intercept determined by the regression analysis,
the estimated size of the processing-induced defect that existed on the surface of the semiconductor wafer before the surface treatment was carried out, at the coordinate point where the processing-induced defect was detected, is determined as the b,
the ozone water has an ozone concentration of 20 ppm or more and 30 ppm or less, based on mass,
the hydrofluoric acid has a hydrogen fluoride concentration of 0.1% by mass or more and 1.0% by mass or less, and
time of the supply of the hydrofluoric acid is 20 sec or less.

8. A method of manufacturing a semiconductor wafer, the method comprising:
manufacturing a semiconductor wafer under a manufacturing condition to be evaluated;
evaluating the manufactured semiconductor wafer by the semiconductor wafer evaluation method according to claim 1;
based on results of the evaluation, determining a manufacturing condition obtained by modifying the manufacturing condition to be evaluated as a subsequent manufacturing condition, or determining the manufacturing condition to be evaluated as a manufacturing condition to be used continuously; and
manufacturing the semiconductor wafer under the determined manufacturing conditions.

9. The method of manufacturing a semiconductor wafer according to claim 8, wherein the manufacturing condition to be modified is a polishing condition of a surface of the semiconductor wafer.
